(19) United States
(12) Patent Application Publication
(10) Pub. No.: US 2010/0248401 A1
(43) Pub. Date: Sep. 30, 2010

(54) Kind of Method of Constituting Light Source using Multiple Light-emitting units

(76) Inventor: William YU, Laytonsville, MD (US)

Correspondence Address: DOWELL & DOWELL P.C., 103 Oronoco St., Suite 220, Alexandria, VA, 22314, US

(21) Appl. No.: 12/708,377

(22) Filed: Feb. 18, 2010

(30) Foreign Application Priority Data
Feb. 18, 2009 (CN) 200910046295.5

(51) Int. Cl. H01L 21/66; H01L 33/00

(52) U.S. Cl. 438/17; 438/28; 257/E21.531; 257/E33.055

(57) ABSTRACT

A method for forming a light source by plurality of light-emitting units, includes: step (A), determining the number of the light-emitting units based on following factors: the factors include a maximum supply voltage of a power supply circuit and a working voltage of each of the light-emitting units; step (B), determining a set power of each of the light-emitting units based on a set power of the light source and the number of the light-emitting units determined in the step (A); step (C), fabricating or selecting each of the light-emitting units based on the working voltage of each of the light emitting units and the set power of each of the light-emitting units determined in the step (B); step D), forming the light source by connecting each of the light-emitting units obtained in the step (C) in series according to the number of the light-emitting units determined in the step (A). For the light source formed as the above method, the high efficient power supply with the maximum output voltage, to the light source load, can be realized and the same power supply circuit can supply power to the light source with different set power with maximum supply efficiency.

### FIELD OF THE INVENTION

The present invention relates to a method for forming a light source, specifically to a method for forming a light source by plurality of light-emitting units.

### DESCRIPTION OF THE BACKGROUND ART

Recently, it is widely popular that plurality of light-emitting units with high light-emitting efficiency, for example plurality of LEDs (Light Emitting Diodes) are connected in series to form a light source, and the said light source is combined with a power supply circuit to form an energy saving lighting device, which is used to replace the conventional incandescent lamp for the purpose of saving energy. In the prior arts, the conventional method for forming this type of lighting device is shown as follows: determining the number of the required light-emitting unit for forming the light source based on the set power of the light source, for example, the rated power (for example, 15 W, 25 W, 40 W, 60 W, 100 W etc, for the incandescent lamp) and the selected standard light-emitting unit with a rated power; then forming the light source by connecting the said number of light emitting units in series. According to the conventional method for forming the light source, the factors for determining the number of the light-emitting units are the set power of the light source and the rated power of the light-emitting units. In the case where the lighting device is formed by such a light source and a power supply circuit, since the working voltage of the light source and the maximum output voltage of the power supply circuit often mismatches (a voltage matching point of a specific power of the light source may exist), the working voltage of the light source is not equal to the maximum outputting voltage of the power supply circuit. In order to solve the problem of the voltage being mismatched, it is necessary that, an electric voltage converter or a resistor connected with the light source in series is connected to the output of the power supply circuit, or a voltage transformer is connected to the input of the power supply circuit. The match between the working voltage of the light source and the output voltage of the power supply circuit is realized by stepping down the voltage or transforming the voltage, i.e., causing the working voltage of the light source to be equal to the output voltage of the power supply circuit. In this way, the power consuming components such as the said resistor, electric voltage converter or voltage transformer and so on are introduced into the power supply circuit, resulting in the reduce of the efficiency of the lighting device.

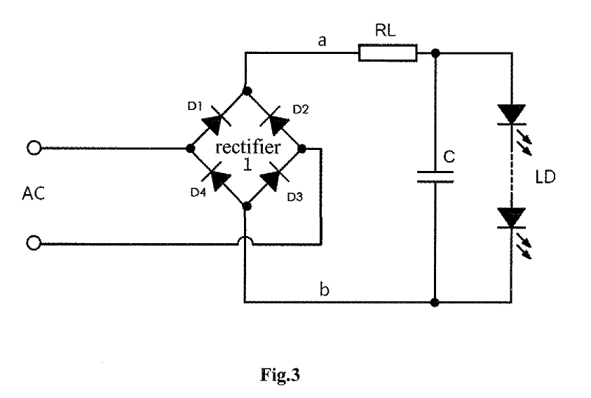

Now, refer to FIG. 3, which illustrates the example of the circuit diagram of the lighting device formed by the light source which is formed according to the conventional method. The lighting device includes a light source LD and a power supply circuit besides the light source LD. In the case where the power supply circuit AC is connected to a power source, for example 220V of commercial voltage, in theory, the maximum value of the output voltage of the power supply circuit reaches 220×1.414=311 V. In the said lighting device, it is assumed that the set power of the light source is 40 W, and the LED of LUXEON (trademark) REBL (type) with the rated power of 1 W (produced by LUMILEDS Company, USA) is selected as the light-emitting unit. According to the above conventional method for forming the light source, the light source LD requires that the number of the LEDs connected in series=40 W/1 W=40, the working voltage of the light source LD=40×the working voltage of each LED (the working voltage of a REBL LED with the rated power of 1 W is about 3.5V, and the working current is about 350 mA)=140V, the working current flowing through the light source LD=the power of the light source 40 W/the working voltage of the light source 140V=about 285 mA. In order to perform the voltage matching between the working voltage of the light source LD and the maximum output voltage of the power supply circuit, it is assumed that the voltage matching is solved by connecting a step down resistor RL connected in series with the light source LD to the output of the power supply circuit of the lighting device. In the case where the light source does not work in the state of constant current (or constant voltage), the maximum output voltage of the power supply circuit is 311 V, here the resistance value of the resistor RL=(the maximum output voltage 331 V−the working voltage of the light source LD 140V)/the working current of the light source 285 mA=about 600 ohm. Assumed that the efficiency of the power supply circuit without connecting dropping resistor RL (the power consumption of the rectifier tube D1-D4 is omitted) is 100%, after the resistor RL of 600 ohm is connected, the efficiency of the power supply circuit=the power of the light source/the input power of the power supply circuit=power of the light source/(power of the light source+the power of the resistor RL)=the working voltage of the light source LD 140V/the maximum output voltage of the power supply circuit 311 V=45%. It can be seen that the efficiency of the power supply circuit drops a lot after the resistor RL is connected. If the maximum output voltage of the power supply circuit 311V is transformed to the working voltage of the light source LD 140V by connecting a voltage transformer to the input of the power supply circuit or connecting an electronic voltage converter to the output of the power supply circuit, instead of the resistor RL, although the power supply efficiency will be improved as compared with the power supply circuit with a connected resistor RL, the efficiency of the power supply circuit will still drop due to the internal resistance, eddy current loss of the voltage transformer, and the consumption of the electronic components inside the electronic voltage converter.

### SUMMARY OF THE INVENTION

The present invention is made to solve the above problems, and the object of the present invention is to provide a method for forming a light source by plurality of light-emitting units, which can realize the power supply with high efficiency to the light source load for the power supply circuit.

The method for forming a light source by plurality of light-emitting units of the present invention, includes:

step (A), determining the number of the light-emitting units based on following factors: the factors include a maximum supply voltage of a power supply circuit and a working voltage of each of the light-emitting units;

step (B), determining a set power of each of the light-emitting units based on a set power of the light source and the number of the light-emitting units determined in the step (A);

step (C), fabricating or selecting each of the light-emitting units based on the working voltage of each of the light emitting units and the set power of each of the light-emitting units determined in the step (B);

step D), forming the light source by connecting each of the light-emitting units obtained in the step (C) in series according to the number of the light-emitting units determined in the step (A).

The factors further include efficiency of the power supply circuit and voltage-varying range of a power source under constant voltage characteristic, the power source supplying the power supply circuit with electric power.

The factors further include efficiency of the power supply circuit and voltage-varying range of a power source under constant current characteristic, the power source supplying the power supply circuit with electric power.

The light-emitting units are LEDs.

For the light source formed according to the above method, since the working voltage of the light source matches with the maximum output voltage of the power supply circuit, the supply efficiency of the power supply circuit can be improved, and the highly efficient power supply with the maximum output voltage, to the light source load, can be realized, as compared with the prior art. Another advantage brought by the method is that, for any light source with different set power, the same power supply circuit can supply power to light source load efficiently with maximum output voltage.

### BRIEF DESCRIPTION OF THE DRAWINGS

### See Drawings

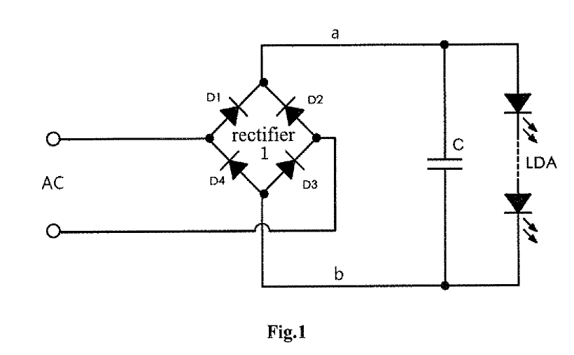

FIG. 1 is the circuit diagram of an example of the lighting device formed by the light source which is formed according to the method for forming the light source of the present invention.

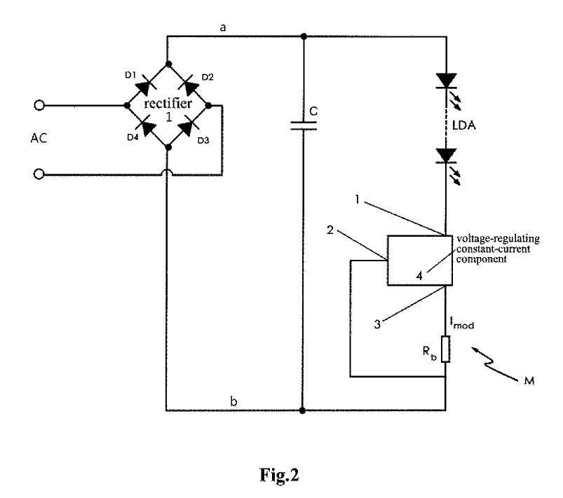

FIG. 2 is the circuit diagram of another example of the lighting device formed by the light source which is formed according to the method for forming the light source of the present invention.

FIG. 3 is an example of the circuit diagram of the lighting device formed by the light source which is formed according to the conventional method.

### DESCRIPTION OF THE PREFERRED EMBODIMENTS

FIG. 1 illustrates the circuit diagram of an example of the lighting source formed by the light source which is formed according to the method for forming the light source of the present invention. Compared with the example of the circuit diagram of the lighting device in the prior art, the step down resistor RL is omitted in the circuit structure of an example of the lighting device according to the present invention. The rest of the circuit structure of the example of the lighting device according to the present invention is as same as those of the circuit as shown in FIG. 3. Although the representation form of light sources LDA of the both circuits is the same, the number of the light-emitting units connected in series and the internal configuration of the both circuits may be different depending on the difference of the method for forming the light source. The case where the components for preventing the light source LDA from not enabling to light normally once the light-emitting unit is in open circuit, such as voltage regulator diode, are connect to the both ends of the light-emitting unit connected in series, is not excluded from the “connection in series” referred herein. The “maximum supply voltage of the power supply circuit” referred herein indicates the output voltage which is supplied to the load (light source) to cause the load (light source) to work normally without connecting electric components with the power consumption to the power supply circuit for the purpose of performing the voltage match for the load, such as light source and the like. For example, in the case where the light-emitting unit is a component working with the constant voltage, it is necessary that the power consuming components for causing the light source to work with the constant voltage (be able to work normally), such as regulating tubes, which is connected with the light source in series, is connected to the output of the power supply circuit; and in the case where the light-emitting unit is a device working with the constant current, such as LED, it is necessary that the power consuming components for causing the light source to work with the constant current (be able to work normally), such as constant-current resistor, which is connected with the light source in series, is connected to the output of the power supply circuit. Such power consuming components, like the said regulating tube and constant-current resistor also need working voltage, therefore, according to the definition of the above-referenced “maximum supply voltage of the power supply circuit”, “the output voltage which is supplied to the light source and causes the light source to work normally”, i.e., the “maximum supply voltage of the power supply circuit” indicates the voltage obtained by subtracting the working voltage of the power consuming components such as the regulating tube connected in series or the consuming components such as the constant-current resistor connected in series from the output of the power supply circuit.

The method for forming a light source by plurality of light-emitting units of the present invention includes:

step (A) determining the number of the light-emitting units based on following factors: the factors include a maximum supply voltage of a power supply circuit and a working voltage of each of the light-emitting units;

step (B) determining a set power of each of the light-emitting units based on a set power of the light source and the number of the light-emitting units determined in the step (A);

step (C) fabricating or selecting each of the light-emitting units based on the working voltage of each of the light emitting units and the set power of each of the light-emitting units determined in the step (B);

step D) forming the light source by connecting each of the light-emitting units obtained in the step (C) in series according to the number of the light-emitting units determined in the step (A).

In one embodiment, the light-emitting unit is a LED, whose working voltage is commonly in a range of 3.0V-3.7V. The specific working voltage of a certain LED can be determined according to the specific fabricating technology of the LED or the existing standard LED. In the step (A), the basic number of the light-emitting units is calculated based on the maximum supply voltage of the power supply circuit and the working voltage of the light-emitting unit firstly, and then the number of the light-emitting unit (the number of the light-emitting unit employed actually in the light source) is determined based on the basic number. The example of embodiment of the above step (A) is shown as follows.

Firstly, the basic number of the light-emitting units (for example, LED) is obtained by dividing the maximum supply voltage of the power supply circuit by the working voltage of the light-emitting unit (for example, LED). In the case where the result of dividing the maximum supply voltage by the working voltage is an integer, the basic number is equal to the said integer; and in the case where the result of dividing is not an integer, i.e., integer+residue, the basic number is equal to the said integer or integer+1.

As for the light source which can work normally without the necessary of working in the state of constant voltage or constant current, the number of the light-emitting units (for example, LED) for forming the light source is equal to the said basic number.

As for the light source which works in the state of constant voltage or constant current, the number of the light-emitting units (for example, LED) for forming the light source may be equal to the basic number, or may be determined by adjusting the basic number based on the requirement for constant voltage or constant current characteristics and the requirement for the efficiency of the power supply circuit. As a specific example, the factor for determining the number of the light-emitting units (for example, LED) can further include the varying range of the voltage of power source under the constant voltage or constant current characteristics, and the efficiency of the power supply circuit. In the case where the varying range of the voltage of power source under the constant voltage or constant current characteristics and the efficiency of the power supply circuit are considered, the specific adjusting manner can be that, the number of the light-emitting units (for example, LED) may be obtained by subtracting/adding 1, 2, 3 or other number from/to the basic number. For example, in the case where the varying range of the voltage of power source under the constant voltage or constant current characteristics is required to be improved, the number of the light-emitting unit (for example, LED) for forming the light source may be obtained by subtracting 1, 2, 3 or other number from the basic number; In the case where the efficiency of the power supply circuit is required to be improved, the number of the light-emitting unit (for example, LED) for forming the light source may be obtained by adding 1, 2, 3 or other number to the basic number.

The greatest difference between the method for forming the light source of the present invention and the prior art lies in that, the principal factor for determining the number of the light-emitting unit is the maximum supply voltage of the power supply circuit and the working voltage of the light-emitting unit, whereas the principal factor for determining the number of the light-emitting unit is the set power of the light source and the rated power of the light-emitting unit. The calculation methods for determining the number of the light-emitting unit based on the respective factor of the both methods are the same. The reason why the method for forming the light source of the present invention can improve the efficiency of the power supply circuit is that, the principal factor as taken is different from that of the prior art, and is independent of the calculation method of the number of the light-emitting units.

The above mentioned method is applicable to any light-emitting units with the working voltage which is lower than the output voltage of the power supply circuit.

Commonly, after the set power of the light-emitting unit is determined according to the step (B), in the step (C), the said light-emitting unit can be fabricated according to any one of the existing or future fabrication technologies because that the present invention is not related to the improvement for the processing technology of the light-emitting unit, and only to the determination of the global criteria of the light-emitting unit, i.e., the working voltage and the set power. So does the LED. The corresponding LED can be fabricated according to the given working voltage and set power as well as a certain fabrication technology. On the other hand, in the case where the fabrication technology has been decided, the area of the chip of the LED is in direct proportion to the power of the LED. In this case, the step of fabricating each of the light-emitting unit in the step (C) further includes: a step (C1) of determining the chip size of each of the light-emitting units (for example, each of LEDs), according to the set power of each of the light-emitting units (for example, each of LEDs) determined in the step (B), referring to the rated power and chip area of the standard light-emitting unit (for example, LEDs), and following the relationship that the chip area is in direct proportion to the power; and step (C2) of fabricating each of the light-emitting units (for example, LEDs) according to the chip size of each of the light-emitting units (for example, each of LEDs) determined in the step (C1) and the fabrication technology of the standard light-emitting unit (for example, LEDs).

Selecting each of the light-emitting units (for example, LEDs) in the above step (C) further includes: selecting the standard light-emitting unit (for example, LEDs) whose rated power is close to the set power as each of the light-emitting units. In this case, the set power can be reached by adjusting the working point of the light source through the circuit. For example, in the case where the light-emitting unit is a LED, the light source is formed by such standard LED; and in the case where the lighting device is formed by the said light source, the light source can be caused to work in the nominal power by adjusting the working current of the nominal LED.

In the above method, for example, the fabrication of the LED is only related to the variation of the chip size of the LED, and is not related to the variation of the other fabrication technologies of the LED. Therefore, any of the existing or future fabrication technologies of the LED can be applicable to the present invention. The specific fabrication technology of the LED will not be described exemplarily.

The application example of the method for forming the light source of the present invention will be described below.

See FIG. 1, for example, the light-emitting unit of the light source employs the LED. In the case where the alternating voltage input by the power supply circuit is 220V, in theory, the maximum supply voltage after rectifying by the rectifier (rectifier diodes D1-D4) of the power supply circuit is 220V×1.414≈311V. In the case where the LED of LUXEON (trademark) REBL (type) with a rated power of 1 W (produced by LUMILEDS Company, USA) is selected as the standard light-emitting unit, the working voltage of the LED is 3.5V, and the working current is 350 mA, under the rated power of 1 W. The power of the light source LDA is set to 40 W. It can be obtained according to the step B) that, the number of the LEDs required by the light source LDA=311V/3.5V≈89. It can be determined according to the step B) that, power of each of the LEDs=40 W/89≈0.45 W. Further, each of the LEDs is fabricated according to the step (C). Also, it can be determined according to the step (C1) that, the chip area of the LED=(0.45 W/1 W)×the chip area of the LED of LUXEON (trademark) REBL (type) with a rated power of 1 W. Further, each of the LEDs of 0.45 W is fabricated by the fabrication technology for the standard LED according to the step (C1), and the light source LDA with the set power of 40 W is formed by connecting 89 LEDs of 0.45 W in series. The light source formed according to the above method has the effect that the power supply circuit can supply power to the light source with a maximum supply efficiency of 100% (the power consumption of the rectifier diodes D1-D4 is omitted). Further, this method has an advantage that the same power supply circuit can supply power to the light source with different set power with maximum supply efficiency.

FIG. 2 illustrates the circuit diagram of another example of the lighting device formed by the light source which is formed according to the method for forming the light source of the present invention. It is a more practicable embodiment as compared with the embodiment of FIG. 1. Since LED commonly needs the constant-current supply to make the lighting of the light source be stable, a circuit for supplying of constant current M is added into the embodiment of FIG. 2, as compared with the embodiment of FIG. 1, and the rest of the structure of FIG. 2 is as same as that of FIG. 1. It can be seen from FIG. 2, the circuit for supplying of constant current M includes a constant-current resistor (a current negative feedback resistor) Rb and voltage-regulating constant-current component 4. In the case where the voltage-regulating constant-current component 4 is, for example, LM117, LM317 or LM388 and so on, the voltage V23 (constant voltage) applied to the both ends of the constant-current resistor Rb is about 2.5V, and the working voltage Vx (i.e., voltage V13) of the voltage-regulating constant-current component 4 is set to 2V, according to the definition of the “maximum supply voltage of the power supply circuit”, the output voltage which is supplied to the load (light source) and causes the load (light source) to work normally is the voltage obtained by subtracting the working voltage of the power consuming components such as constant-current resistor from the output of the power supply circuit, i.e., 311V−2.5V−2V=306.5V, wherein 311V is the output (output voltage) of the power supply circuit, 2.5V is the working voltage of the constant-current resistor Rb, 2V is the working voltage of the voltage-regulating constant-current component 4 as the power consuming component, 306.5V is the maximum supply voltage of the power supply circuit.

After the maximum supply voltage of the power supply circuit, 306.5V has been obtained, the rest of the steps for forming the light source are as the same as those in the embodiment of FIG. 1. For example, the light-emitting unit is a LED whose working voltage is 3.5V. The set power of the light source is 40 W. The number of the light-emitting units forming the light source is 306.5/3.5=87.57. According to the method of the present invention, 87 can be taken as the number of the light-emitting units forming the light source, and here the redundant voltage of the light source=306.5−3.5×87=2V, which can be distributed to the circuit for supplying of constant current M, specifically, to the voltage-regulating constant-current component 4. In this way, the working voltage of the voltage-regulating constant-current component 4, V13=2V+2V=4V, and thus the varying range of the voltage of the power source under the constant current characteristic is improved; 86 can be taken as the number of the light-emitting units forming the light source, and here the redundant voltage of the light source is 2V+3.5V=5.5V, which can be distributed to the circuit for supplying of constant current M, specifically, to the voltage-regulating constant-current component 4. In this way, the working voltage of the voltage-regulating constant-current component 4, V13=2V+5.5V=7.5V, and thus the varying range of the voltage of the power source under the constant characteristic is further improved; 88 can be taken as the number of the light-emitting units forming the light source, and here the redundant voltage of the light source=311−(87×3.5)=3, which can be distributed to the circuit for supplying of constant-current M. In order to secure the set power of 40 W of the light source to be unchanged, the voltage of the both ends of the constant-current resistor Rb, V23 (constant voltage) is unchanged and is about 2.5V, so the working voltage of the voltage-regulating constant-current component 4 is 0.5V, and thus the varying range of the voltage of the power source under the constant current characteristic decreases, however, the efficiency of the power supply circuit can be further improved.

The efficiency of the power supply circuit in the embodiment of FIG. 2 is calculated as follows. For the number of the LEDs of the light source is 86, the efficiency of the power supply circuit (the loss of the rectifier diodes D1-D4 is neglected)=86×3.5V/311V=96.7%; for the number of the LEDs of the light source is 88, the efficiency of the power supply circuit=88×3.5V/311V=99%.

The invention is described in detail in conjunction with the drawings. A person skilled in the art can make other modifications, other than the modification described in the description, according to the conception of the invention disclosed by the specification. Therefore, the embodiments and the modifications thereof described in the specification should not be treated as the limitation to the present invention. The present invention should be defined by the appended claims embodying the conception of the present invention.

What is claimed:

1. A method for forming a light source by plurality of light-emitting units, includes:
step (A), determining the number of the light-emitting units based on following factors: the factors include a maximum supply voltage of a power supply circuit and a working voltage of each of the light-emitting units;
step (B), determining a set power of each of the light-emitting units based on a set power of the light source and the number of the light-emitting units determined in the step (A);
step (C), fabricating or selecting each of the light-emitting units based on the working voltage of each of the light emitting units and the set power of each of the light-emitting units determined in the step (B);
step D), forming the light source by connecting each of the light-emitting units obtained in the step (C) in series according to the number of the light-emitting units determined in the step (A).

2. The method as described in claim 1, characterized in that, the factors further include efficiency of the power supply circuit and voltage-varying range of a power source under constant voltage characteristic, the power source supplying the power supply circuit with electric power.

3. The method as described in claim 1, characterized in that, the factors further include efficiency of the power supply circuit and voltage-varying range of a power source under constant current characteristic, the power source supplying the power supply circuit with electric power.

4. The method as described in claim 1 or 3, characterized in that, the light-emitting units are LEDs.

5. The method as described in any one of claim 1 to 3, characterized in that, the step of fabricating each of the light-emitting units in the step (C) further includes: step (C1) of determining a chip size of each of the light-emitting units, according to the set power of each of the light-emitting units determined in the step (B), referring to a rated power and chip area of a standard light-emitting unit, and following the relationship that the chip area is in direct proportion to the power; and step (C2) of fabricating each of the light-emitting units according to the chip area of each of the light-emitting units determined in the step (C1) and a fabrication technology of the standard light-emitting unit.

6. The method as described in claim 5, characterized in that, the light-emitting units are LEDs.

7. The method as described in any one of claim 1 to 3, characterized in that, the step of selecting each of the light-emitting units in the step (C) further includes, selecting a standard light-emitting unit whose rated power is close to the set power as each of the light-emitting units.

8. The method as described in claim 7, characterized in that, the light-emitting units are LEDs.
